(19) United States
(12) Patent Application Publication
(10) Pub. No.: US 2026/0041008 A1
(43) Pub. Date: Feb. 5, 2026

(54) LOGIC-UPPERMOST SEMICONDUCTOR DEVICE ASSEMBLIES WITH RECONSTITUTED WAFERS AND MULTI-RETICLE DIES COUPLED BY RETICLE-BRIDGING CONDUCTORS

(71) Applicant: Micron Technology, Inc., Boise, ID (US)

(72) Inventors: Bharat Bhushan, Singapore (SG); Kunal R. Parekh, Boise, ID (US); Akshay N. Singh, Boise, ID (US); Mark Zaleski, Boise, ID (US); Ameen D. Akel, Rancho Cordova, CA (US); Bret K. Street, Meridian, ID (US)

(21) Appl. No.: 19/281,140

(22) Filed: Jul. 25, 2025

Related U.S. Application Data
(60) Provisional application No. 63/677,978, filed on Jul. 31, 2024.

(51) Int. Cl. H01L 25/18; H01L 23/00; H01L 23/31; H01L 23/48; H01L 23/538; H10B 80/00; H10D 80/30

(52) U.S. Cl. CPC H01L 25/18; H01L 23/3128; H01L 24/08; H01L 24/24; H01L 24/80; H10B 80/00; H10D 80/30; H01L 23/481; H01L 23/538; H01L 2224/08145; H01L 2224/08225; H01L 2224/24137; H01L 2224/24146; H01L 2224/80895; H01L 2224/80896; H01L 2225/06541

(57) ABSTRACT

A semiconductor device assembly includes a plurality of stacks of semiconductor devices horizontally spaced apart by a gap fill material, each including multiple devices coupled by TSVs to external package contacts through an RDL, and a device connection layer formed over the stacks and including a first plurality of contacts coupled to the TSVs, a second plurality of contacts facing away from the TSVs, a first plurality of conductors coupling contacts of the first plurality to corresponding contacts of the second plurality, and a second plurality of conductors coupling contacts of the second plurality to other contacts of the second plurality. The assembly further includes a multi-reticle semiconductor device over the device connection layer and including a plurality of circuit regions horizontally spaced apart from one another by a reticle-edge region absent any electrical conductors. The second plurality of conductors in the device connection layer operably interconnect the circuit regions.

### CROSS-REFERENCE TO RELATED APPLICATION(S)

The present application claims priority to U.S. Provisional Patent Application No. 63/677,978, filed Jul. 31, 2024, the disclosure of which is incorporated herein by reference in its entirety.

### TECHNICAL FIELD

The present disclosure generally relates to semiconductor device assemblies, and more particularly relates to logic-uppermost semiconductor device assemblies with reconstituted wafers and multi-reticle dies coupled by reticle-bridging conductors.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIGS. 1 through 5 are simplified schematic cross-sectional views of different stages of the manufacturing process of an example semiconductor device assembly in accordance with embodiments of the present technology.

FIGS. 6 through 12 are simplified schematic cross-sectional views of different stages of the manufacturing process of another example semiconductor device assembly in accordance with embodiments of the present technology.

FIGS. 13 through 18 are simplified schematic cross-sectional views of different stages of the manufacturing process of a yet another example semiconductor device assembly in accordance with embodiments of the present technology.

FIG. 19 is a simplified schematic partial plan view of a semiconductor device assembly in accordance with embodiments of the present technology.

FIG. 20 is a flow chart illustrating a method of making a semiconductor device assembly in accordance with an embodiment of the present technology.

FIG. 21 is a schematic view showing a system that includes a semiconductor device assembly configured in accordance with an embodiment of the present technology.

### DETAILED DESCRIPTION

The demand for greater performance from semiconductor devices appears to be insatiable. To increase the performance of a device, more features can be included in a device of given size by shrinking the feature dimensions through lithography improvements. As feature shrink nears theoretical limits, however, adding more features has driven an increase in the size (i.e., footprint) of semiconductor devices. With the footprint of semiconductor devices increasing up to the limit of lithographic reticle size (a limit which would require dramatic re-tooling of an entire industry to overcome), increasing the capability of semiconductor devices may be accomplished by integrating multiple reticle-limited semiconductor devices into a single assembly.

Reticle-limited semiconductor devices have a footprint greater than the size of a single reticle field (e.g., current EUV reticle sizes are limited to about 858 mm²) and include multiple reticle-sized circuit areas that, due to the limitations of accurately aligning two different reticle fields, may be spaced apart from one another by a region of un-patterned silicon substrate with no conductors or other circuit features therein (e.g., resembling two discrete dies in an un-singulated portion of a semiconductor wafer). Unlike two discrete dies in an un-singulated portion of semiconductor substrate, however, in a reticle-limited semiconductor device the multiple reticle-limited circuit areas may not be designed identically, however, and may include features intended to connected to each other across the un-patterned region of the substrate (e.g., by subsequent BEOL metallization or by connected to an interposer).

A challenge with these approaches to coupling the discrete circuit regions of a multi-reticle semiconductor device is the additional manufacturing cost, package size (e.g., from a dedicated interposer with solder bond line) and increased circuit path length (e.g. interposed between the multi-reticle semiconductor device and its host and/or between the multi-reticle semiconductor device and auxiliary devices integrated with it, such as memory). To solve these drawbacks and others, embodiments of the present disclosure provide semiconductor device assemblies with a prefabricated device connection layer that can be directly bonded, in a wafer-level operation, to a multi-reticle semiconductor device. The device connection layer can couple not only the discrete circuit regions of the multi-reticle semiconductor device to each other, but also the multi-reticle semiconductor device to other semiconductor devices in a heterogenous device assembly, such as memory, as well as to external package contacts (e.g., by conductive paths extending through the other semiconductor devices in the assembly).

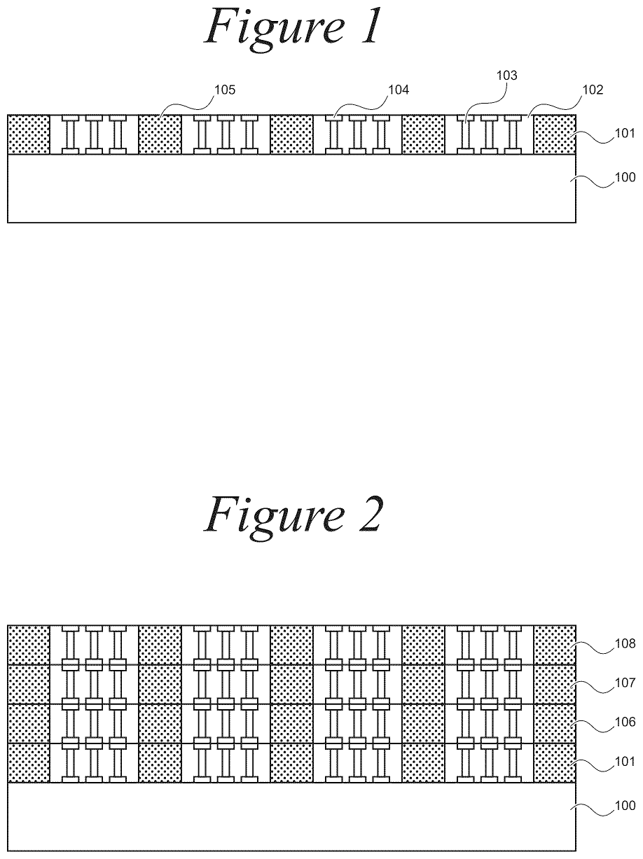

FIGS. 1 through 5 are simplified schematic cross-sectional views of different stages of the manufacturing process of an example semiconductor device assembly in accordance with embodiments of the present technology. Turning to FIG. 1, multiple semiconductor memory devices 102 are provided in a reconstituted wafer 101 of known good dies, provided on a carrier 100. The memory devices 102 include contact structures 104 and TSVs 103 for forming interconnects with additional devices by a wafer-level hybrid bonding process. The memory devices 102 are surrounded by a gap fill material 105, which may be silicon oxide, silicon nitride, or even a mold (e.g., resin-based encapsulant) material. As shown in FIG. 2, additional reconstituted wafers 106-108 with additional semiconductor devices can be hybrid-bonded to form stacks of devices coupled by the contact structures 104 and TSVs 103 vertically aligned therewith.

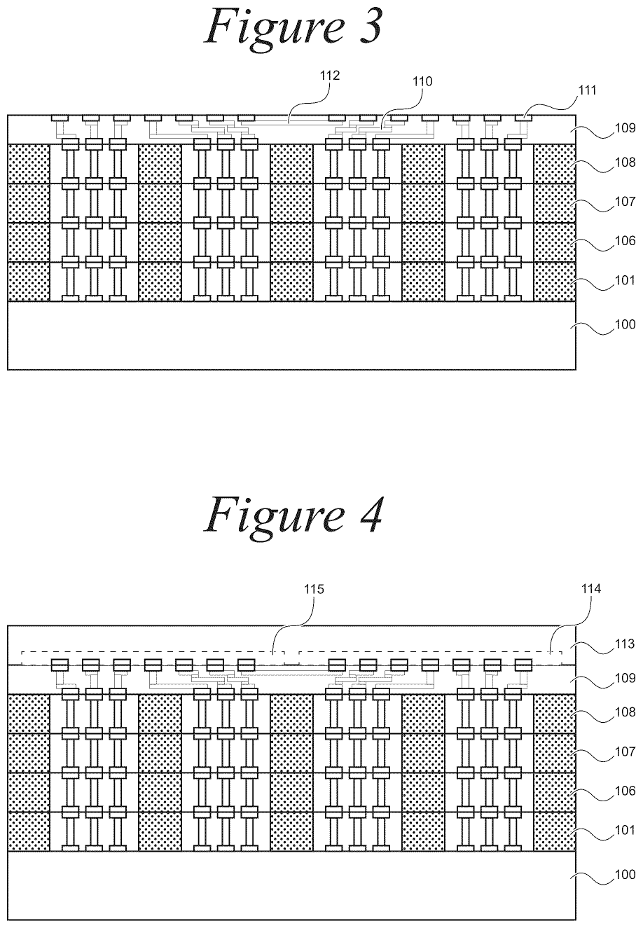

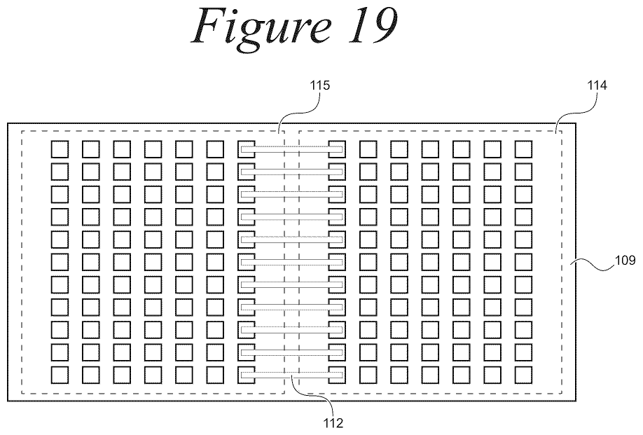

As is illustrated in FIG. 3, a device connection layer 109 can be formed over the stack of wafers 101 and 106-108 from FIG. 2. The device connection layer 109 can be formed like a redistribution layer, with back end of line (BEOL) metallization processes well known to those of skill in the art. For example, iteratively depositing and patterning dielectric material, and plating metal such as copper into the patterned openings in the dielectric material, permits the construction of metal contacts 111 both facing the exposed contacts 104 of wafer 108 and outwardly from the stack, as well as the conductive metal structures 110 that couple the contacts 111 on the wafer-facing (i.e., lower in the orientation of FIG. 3) side of the device connection layer 109 to contacts 111 on the outwardly-facing (i.e., upper in the orientation of FIG. 3) side of the device connection layer 109. The contacts 111 on the outwardly facing side of the device connection layer 109 include a subset that are not coupled to wafer-facing contacts but are rather coupled by reticle-bridging conductors 112 (one pair is shown in the cross-sectional view of FIG. 4, additional pairs of the subset are illustrated in FIG. 19, below). The reticle-bridging conductors 112 can provide inter-region connectivity to a multi-reticle semiconductor device with multiple discrete circuit regions, as shown and described in greater detail below.

Turning to FIG. 4, a wafer 113 including a multi-reticle semiconductor device with two discrete reticle-limited circuit regions 114 and 115 has been hybrid-bonded (i.e., with a dielectric-dielectric bond in regions without conductive contacts, and with a solder-free direct metal-metal bond in regions where contacts of wafer 113 align with the contacts 111 of the device connection layer 109) to the device connection layer 109. In one aspect, the two discrete reticle-limited circuit regions 114 and 115 are graphical processing units (GPUs) or central processing units (CPUs). The wafer 113 is bonded to device connection layer 109 by way of wafer-on-wafer bonding, especially in back-to-front (B2F) configuration. Because of the reticle-limited size of the circuit regions 114 and 115, there are no conductors disposed within the region separating them, and prior to bonding the wafer 113 to the device connection layer 109, the circuit regions 114 and 115 are electrically isolated from one another. After the bonding operation however, reticle-bridging conductors 112 operably couple contacts from one circuit area 114 to the other 115, providing inter-region connectivity and permitting the multi-reticle semiconductor device to function as a single integrated device.

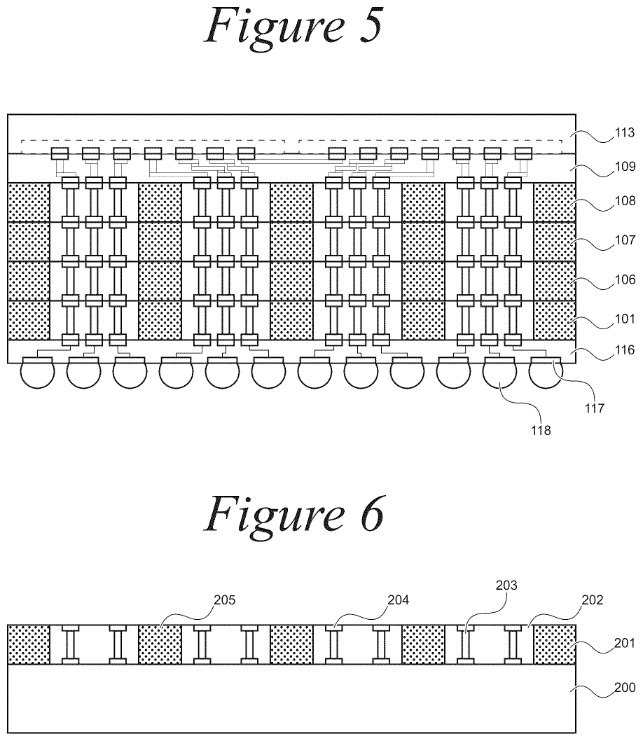

As is illustrated in FIG. 5, after removing the carrier 100, a redistribution layer (RDL) 116 can be to on the stack of wafers 101 and 106-108 from FIG. 4. The RDL 116 can be formed with back end of line (BEOL) metallization processes well known to those of skill in the art. For example, iteratively depositing and patterning dielectric material, and plating metal such as copper into the patterned openings in the dielectric material, permits the construction of external contacts 117 and internal contacts (not labeled), as well as the conductive metal structures that couple the internal contacts and external contacts 117 to each other. Solder balls 118 can be formed on the external contacts 117 of RDL 116 for connection to higher-level devices, and the wafer stack can also be singulated at this point, such that the sidewalls illustrated in the Figure correspond to exterior surfaces of the singulated device.

In accordance with another aspect of the present disclosure, the assembly illustrated in FIG. 5 can be modified to include through-gap fill vias for connecting the RDL 116 directly to the device connection layer 109, so that signals (e.g., i/o, ground, power, etc.) can be directly provided to the multi-reticle semiconductor device from an external package contact without connecting to circuit elements of the semiconductor devices (e.g., memory devices) between the RDL 116 and the device connection layer 109. For example, FIGS. 6 through 12 are simplified schematic cross-sectional views of different stages of the manufacturing process of an example semiconductor device assembly in accordance with embodiments of the present technology.

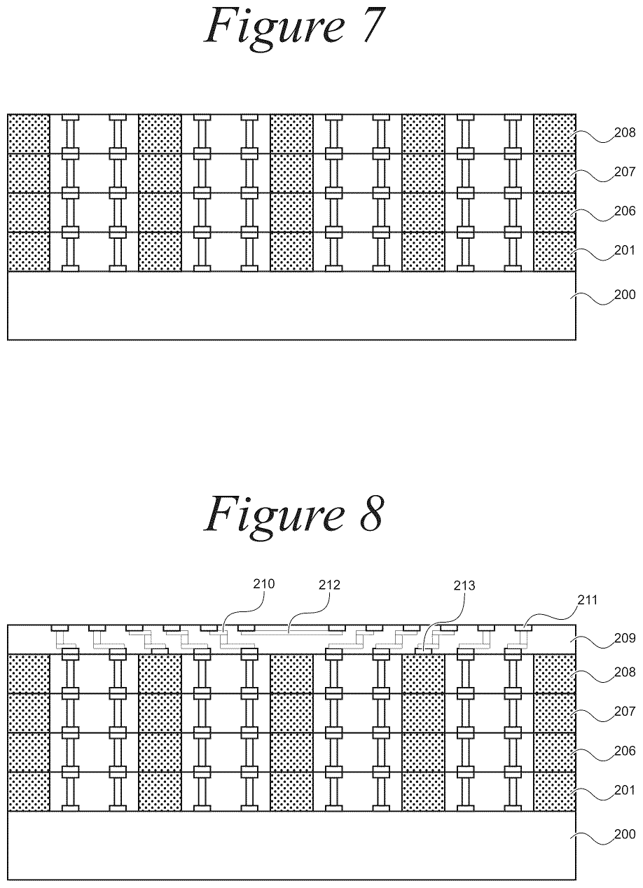

As shown in FIGS. 6 and 7, in steps analogous to those illustrated in FIGS. 1 and 2, above, a stack of wafers 201 and 206-208 with additional semiconductor devices can be hybrid-bonded to one another while carried by a carrier 200 to form stacks of devices coupled by the contact structures 204 and TSVs 203 vertically aligned therewith. Turning to FIG. 8, a device connection layer 209 can be formed over the stack of wafers 201 and 206-208 from FIG. 7. The device connection layer 209 can be formed like a redistribution layer, with back end of line (BEOL) metallization processes well known to those of skill in the art. For example, iteratively depositing and patterning dielectric material, and plating metal such as copper into the patterned openings in the dielectric material, permits the construction of metal contacts 211 both facing the exposed contacts 204 of wafer 208 and outwardly from the stack, as well as the conductive metal structures 210 that couple the contacts 211 on the wafer-facing (i.e., lower in the orientation of FIG. 8) side of the device connection layer 209 to contacts 211 on the outwardly-facing (i.e., upper in the orientation of FIG. 8) side of the device connection layer 209. The contacts 211 on the outwardly facing side of the device connection layer 209 include a subset that are not coupled to wafer-facing contacts 211 but are rather coupled by reticle-bridging conductors 212 (one pair is shown in the cross-sectional view of FIG. 8, additional pairs of the subset are illustrated in FIG. 19, below). The reticle-bridging conductors 212 can provide inter-region connectivity to a multi-reticle semiconductor device with multiple discrete circuit regions, as shown and described in greater detail below. The device connection layer 209 further includes contacts 213 not aligned with TSVs 203 or contact structures 204 of the wafers 201 and 206-208, for connection to a through-gap fill via in a later step.

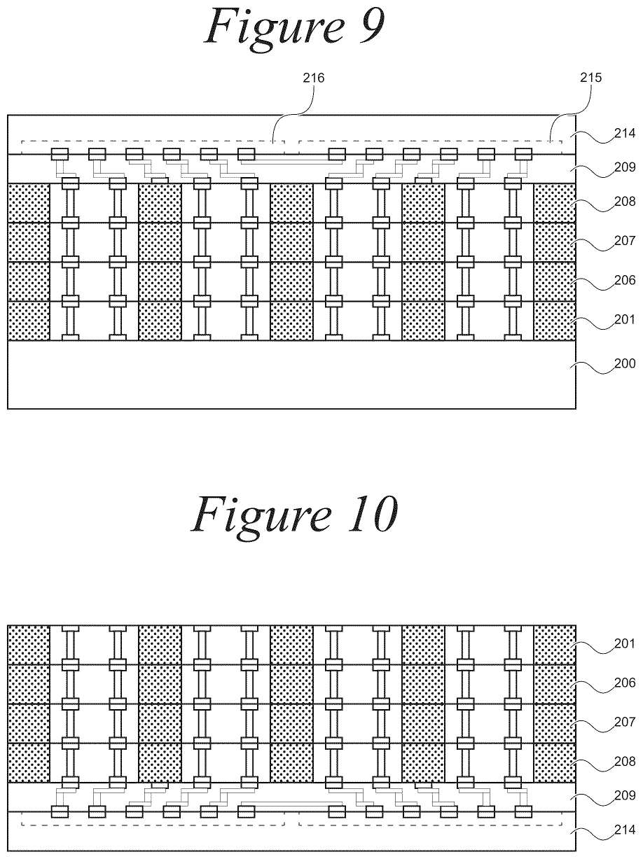

Turning to FIG. 9, a wafer 214 including a multi-reticle semiconductor device with two discrete reticle-limited circuit regions 215 and 216 has been hybrid-bonded (i.e., with a dielectric-dielectric bond in regions without conductive contacts, and with a solder-free direct metal-metal bond in regions where contacts of wafer 214 align with the contacts 211 of the device connection layer 209) to the device connection layer 209. Because of the reticle-limited size of the circuit regions, there are no conductors disposed within the region separating them, and prior to bonding the wafer 214 to the device connection layer 209, the circuit regions are electrically isolated from one another. After the bonding operation however, reticle-bridging conductors 212 operably couple contacts from one circuit area to the other, providing inter-region connectivity and permitting the multi-reticle semiconductor device to function as a single integrated device. After the bonding operation, the carrier 200 can be removed, as shown in FIG. 10.

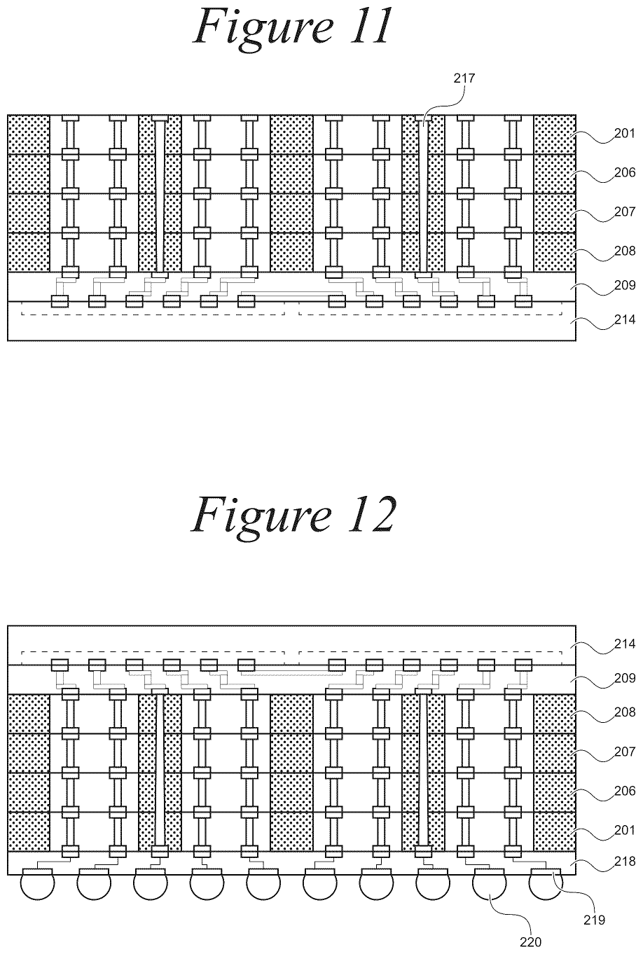

Turning to FIG. 11, though-gap fill vias 217 can be formed through the gap fill material of wafers 201 and 206-208 by etching an opening aligned with the contact structures 213 of the device connection layer 209 and plating a conductive metal (e.g., copper, tungsten, etc.) into the opening. The process may be a dual-damascene process, such as is commonly used to form TSVs with integrated contact pads. Due to the aspect ratio of the etching operation, a continuous taper from one end to the other of the through-gap fill vias 217 may be observed.

Turning to FIG. 12, an RDL 218 is illustrated having been formed over the stack of wafers 201 and 206-286 as shown in FIG. 12. The RDL 218 can be formed with back end of line (BEOL) metallization processes well known to those of skill in the art. For example, iteratively depositing and patterning dielectric material, and plating metal such as copper into the patterned openings in the dielectric material, permits the construction of external contacts 219 and internal contacts (not labeled), as well as the conductive metal structures that couple the internal contacts and external contacts 219 to each other. Solder balls 220 can be formed on the external contacts 219 of RDL 218 for connection to higher-level devices, and the wafer stack can also be singulated at this point, such that the sidewalls illustrated in the Figure correspond to exterior surfaces of the singulated device.

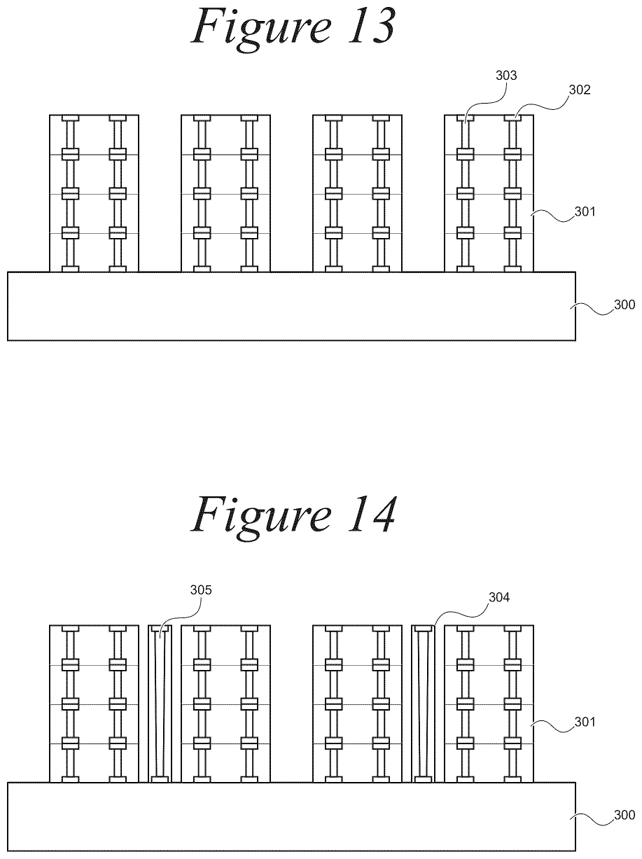

Although in the foregoing example embodiments semiconductor device assemblies have been illustrated with stacks of memory devices formed by wafer-level bonding operations of reconstituted wafers with known good dies, in other embodiments a stack-to-wafer or a combination of chip-to-wafer and chip-to-chip bonding operations can be utilized to form the plurality of stacks of memory devices in an assembly. For example, FIG. 13 illustrates a structure in which stacks 301 of memory devices are provided on a carrier 300. The memory devices include contact structures 302 and TSVs 303 for interconnecting the stacks with each other and with later-added devices.

An optional benefit of forming stacks 301 on the carrier 300 prior to providing a gap fill or encapsulant material is illustrated in FIG. 14, in which silicon slugs 304 having a continuous body of silicon with a height equivalent to the stacks 301 is provide don the carrier. Each of the silicon slugs including one or more TSVs, each comprising a continuously tapering body of conductive metal that is configured to electrically couple a device connection layer to an RDL on opposing sides of the stacks 301 without passing through or being electrically coupled to devices in the stack.

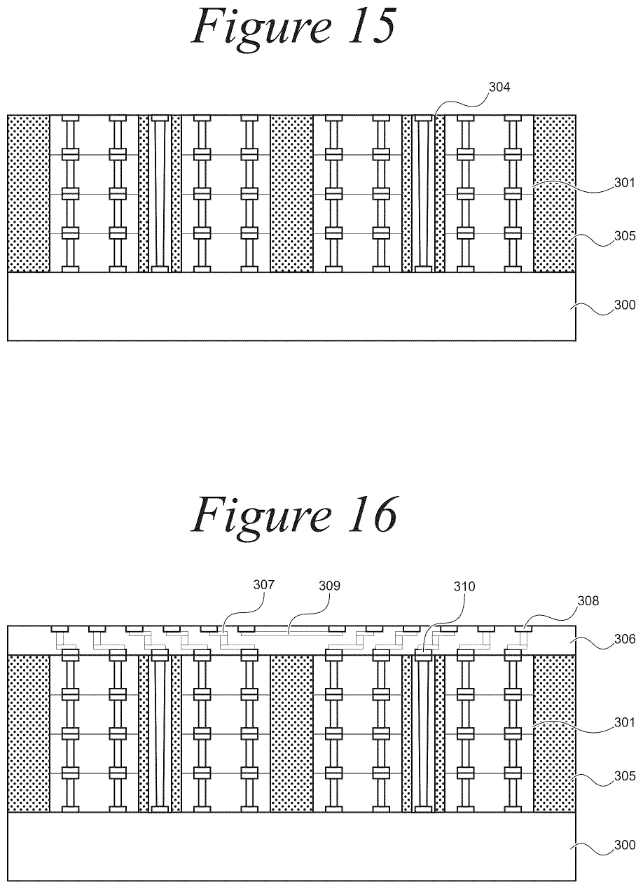

In FIG. 15, a gap fill material 305 is provided to surround the stacks 301 and the silicon slugs 304. The gap fill material 305 is free from seams in the region adjacent the stacks 301 and the slugs 304 (as compared to the gap fill material in assemblies fabricated from reconstituted wafers illustrated above). Although not so illustrated, at this point through-gap fill vias can be provided in addition to or in alternative to the silicon slugs, mutatis mutandis.

Turning to FIG. 16, a device connection layer 306 can be formed over the sub-assembly from FIG. 15. The device connection layer 306 can be formed like a redistribution layer, with back end of line (BEOL) metallization processes well known to those of skill in the art. For example, iteratively depositing and patterning dielectric material, and plating metal such as copper into the patterned openings in the dielectric material, permits the construction of metal contacts 308 both facing the exposed contacts 204 of the stacks 301 and outwardly from the sub-assembly, as well as the conductive metal structures 307 that couple the contacts 308 on the stack-facing (i.e., lower in the orientation of FIG. 16) side of the device connection layer 306 to contacts 308 on the outwardly-facing (i.e., upper in the orientation of FIG. 16) side of the device connection layer 306. The contacts 308 on the outwardly facing side of the device connection layer 306 include a subset that are not coupled to stack-facing contacts 308 but are rather coupled by reticle-bridging conductors 309 (one pair is shown in the cross-sectional view of FIG. 12, additional pairs of the subset are illustrated in FIG. 19, below). The reticle-bridging conductors 309 can provide inter-region connectivity to a multi-reticle semiconductor device with multiple discrete circuit regions, as shown and described in greater detail below. The device connection layer 306 further includes contacts 310 not aligned with the stacks 301, which are bonded to the vias in the silicon slugs 304 (or may, in other embodiments, be bonded to through-gap fill vias).

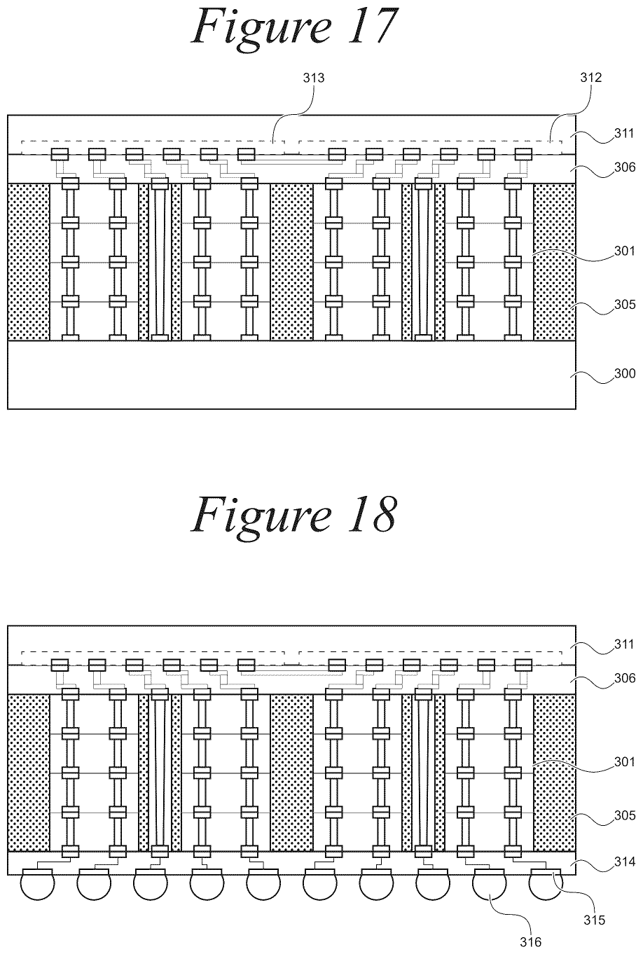

Turning to FIG. 17, a wafer 311 including a multi-reticle semiconductor device with two discrete reticle-limited circuit regions 312 and 313 has been hybrid-bonded (i.e., with a dielectric-dielectric bond in regions without conductive contacts, and with a solder-free direct metal-metal bond in regions where contacts of wafer 311 align with the contacts 308 of the device connection layer 306) to the device connection layer 306. Because of the reticle-limited size of the circuit regions, there are no conductors disposed within the region separating them, and prior to bonding the wafer 311 to the device connection layer 306, the circuit regions are electrically isolated from one another. After the bonding operation however, reticle-bridging conductors 309 operably couple contacts from one circuit area to the other, providing inter-region connectivity and permitting the multi-reticle semiconductor device to function as a single integrated device.

As is illustrated in FIG. 18, after removing the carrier 300, a redistribution layer (RDL) 314 can be to on the sub-assembly from FIG. 17. The RDL 314 can be formed with back end of line (BEOL) metallization processes well known to those of skill in the art. For example, iteratively depositing and patterning dielectric material, and plating metal such as copper into the patterned openings in the dielectric material, permits the construction of external contacts 315 and internal contacts (not labeled), as well as the conductive metal structures that couple the internal contacts and external contacts 315 to each other. Solder balls 316 can be formed on the external 315 of RDL 314 for connection to higher-level devices, and the wafer stack can also be singulated at this point, such that the sidewalls illustrated in the Figure correspond to exterior surfaces of the singulated device.

Turning to FIG. 19, a simplified schematic partial plan view of a semiconductor device assembly in accordance with embodiments of the present technology illustrates additional details of the device connection layer 109. As can be seen with reference to FIG. 19, device connection layer 109 includes multiple reticle-bridging conductors 112 arranged to electrically connect pair of contacts 111 associated with the discrete reticle-limited circuit areas 114 and 115 of the multi-reticle semiconductor device. Although in the present example embodiment, a multi-reticle semiconductor device is illustrated and described as including two discrete circuit areas 114 and 115, in other embodiments a multi-reticle semiconductor device can include more than two circuit areas, and the reticle bridging conductors 112 of the device connection layer 109 may couple contacts 111 to one another in a one-to-one, a one-to-many, and/or a many-to-many topology, as may be desirable for different multi-reticle semiconductor device designs. In one aspect, there may be more than 10,000 reticle-bridging conductors 111.

Although in the foregoing example embodiments semiconductor device assemblies have been illustrated with two stacks of memory devices on a single multi-reticle semiconductor device, in other embodiments greater or lesser numbers of stacks may be provided over a multi-reticle semiconductor device. Moreover, memory devices so provided may comprise a single type of memory, (e.g., NAND or DRAM or PCM or SRAM or MRAM, etc.) or a mixture of different types of memory (e.g., NAND and/or DRAM and/or PCM and/or SRAM and/or MRAM, etc.). Still further, although stacks have been illustrated with four memory devices vertically aligned, in other embodiments different stack heights may be implemented with fewer (e.g., one, two, or three) or more (e.g., five, six, eight, ten, twelve, etc.) layers of memory devices.

Although in the foregoing example embodiments, multi-reticle semiconductor device wafers have been illustrated as including multiple circuit areas in a continuous area of silicon, in other embodiments multi-reticle semiconductor devices can be provided in a reconstituted or heterogenous device wafer.

Although in the foregoing example embodiments semiconductor device assemblies have been illustrated and described as being formed with two reticle-limited circuits, in other embodiments, assemblies can be formed with more than two such reticle limited circuits (e.g., an array of 3×1 such reticle-limited circuits, an array of 2×2 such circuits, or even arrays of 3×2, 4×2, 4×3, etc.). In such arrays, reticle bridging conductors may extend in at least two different directions (e.g. perpendicular to one another).

Although in the foregoing example embodiments semiconductor device assemblies have been illustrated with wafers facing the same direction (e.g., with active surfaces bonded to inactive surfaces), in other embodiments a stack of wafers may be bonded with active surfaces facing in different directions (or, mutatis mutandis, all facing the opposite way than illustrated, with back surfaces facing the external package contacts).

Although in the foregoing example embodiments semiconductor device assemblies have been illustrated with wafers bonded exclusively with a hybrid bonding approach, in other embodiments other wafer bonding approaches (e.g., solder interconnects) could be used in the alternative or additionally.

In accordance with one aspect of the present disclosure, the semiconductor devices illustrated in the assemblies of FIGS. 1-6 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, accelerator dies, etc.), or a mix of logic and memory dies (e.g., a memory controller die and a memory die controlled thereby).

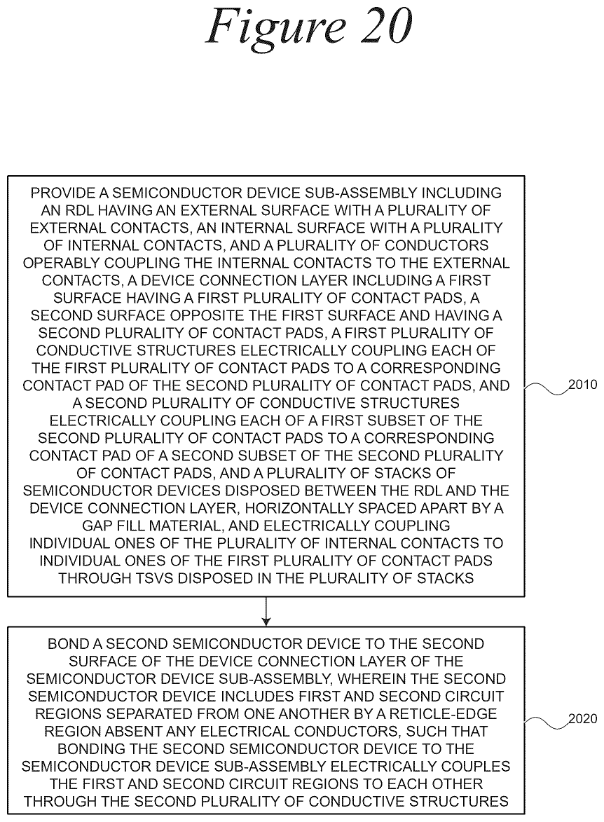

FIG. 20 is a flow chart illustrating a method of making a semiconductor device assembly. The method includes providing a semiconductor device sub-assembly including an RDL having an external surface with a plurality of external contacts, an internal surface with a plurality of internal contacts, and a plurality of conductors operably coupling the internal contacts to the external contacts, a device connection layer including a first surface having a first plurality of contact pads, a second surface opposite the first surface and having a second plurality of contact pads, a first plurality of conductive structures electrically coupling each of the first plurality of contact pads to a corresponding contact pad of the second plurality of contact pads, and a second plurality of conductive structures electrically coupling each of a first subset of the second plurality of contact pads to a corresponding contact pad of a second subset of the second plurality of contact pads, and a plurality of stacks of semiconductor devices disposed between the RDL and the device connection layer, horizontally spaced apart by a gap fill material, and electrically coupling individual ones of the plurality of internal contacts to individual ones of the first plurality of contact pads through TSVs disposed in the plurality of stacks (box 2010). The method further includes bonding a second semiconductor device to the second surface of the device connection layer of the semiconductor device sub-assembly, wherein the second semiconductor device includes first and second circuit regions separated from one another by a reticle-edge region absent any electrical conductors, such that bonding the second semiconductor device to the semiconductor device sub-assembly electrically couples the first and second circuit regions to each other through the second plurality of conductive structures (box 2020).

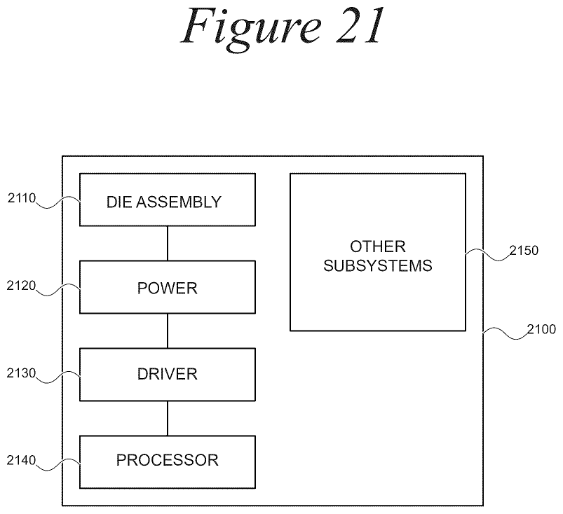

Any one of the semiconductor devices and semiconductor device assemblies described above with reference to FIGS. 1-19 can be incorporated into any of a myriad of larger and/or more complex systems, a representative example of which is system 2100 shown schematically in FIG. 21. The system 2100 can include a semiconductor device assembly (e.g., or a discrete semiconductor device) 2102, a power source 2104, a driver 2106, a processor 2108, and/or other subsystems or components 2110. The semiconductor device assembly 2102 can include features generally similar to those of the semiconductor devices described above with reference to FIGS. 1-19. The resulting system 2100 can perform any of a wide variety of functions, such as memory storage, data processing, and/or other suitable functions. Accordingly, representative systems 2100 can include, without limitation, hand-held devices (e.g., mobile phones, tablets, digital readers, and digital audio players), computers, vehicles, appliances and other products. Components of the system 2100 may be housed in a single unit or distributed over multiple, interconnected units (e.g., through a communications network). The components of the system 2100 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.\

In other embodiments, the term “substrate” can refer to a package-level substrate upon which other semiconductor devices are carried, such as a printed circuit board (PCB), an interposer, or another semiconductor device.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a plurality of stacks of semiconductor devices horizontally spaced apart by a gap fill material, each stack of the plurality including multiple vertically-aligned semiconductor devices operably coupled by through-silicon vias (TSVs) to a plurality of external package contacts through a redistribution layer (RDL);
a device connection layer formed over the plurality of stacks of semiconductor devices and including a first plurality of contacts facing and coupled to the TSVs, a second plurality of contacts facing away from the TSVs, a first plurality of conductors operably coupling individual contacts of the first plurality to corresponding individual contacts of the second plurality, and a second plurality of conductors operably coupling individual contacts of the second plurality to other individual contacts of the second plurality; and
a multi-reticle semiconductor device disposed over the device connection layer, the multi-reticle semiconductor device including a plurality of circuit regions horizontally spaced apart from one another by a reticle-edge region absent any electrical conductors,
wherein the second plurality of conductors in the device connection layer operably interconnect the plurality of circuit regions.

2. The semiconductor device assembly of claim 1, wherein the gap fill material comprises silicon oxide, silicon nitride, a mold material, or a combination thereof.

3. The semiconductor device assembly of claim 1, wherein the plurality of circuit regions of the multi-reticle semiconductor device is disposed face the device connection layer.

4. The semiconductor device assembly of claim 1, wherein the second plurality of conductors extends horizontally under the reticle-edge region of the multi-reticle semiconductor device.

5. The semiconductor device assembly of claim 1, wherein:
the multi-reticle semiconductor device includes a first bonding surface including a first planar dielectric surface and a third plurality of contacts, and
the device connection layer includes a second bonding surface including a second planar dielectric surface and the second plurality of contacts, and
the first bonding surface and the second bonding surface are hybrid-bonded to one another such that the first planar dielectric surface and the second planar dielectric surface are bonded by a dielectric-dielectric bond and such that each of the second plurality of contact pads is bonded to a corresponding one of the third plurality of contact pads by a metal-metal bond exclusive of any solder.

6. The semiconductor device assembly of claim 1, further comprising a plurality of through-gap fill vias extending from the device connection layer to the RDL, each of the through-gap fill vias comprising a continuously tapering body of conductive metal.

7. The semiconductor device assembly of claim 6, wherein each through-gap fill via of the plurality of through-gap fill vias electrically couples the multi-reticle semiconductor device to an external package contact of the plurality of external package contacts exclusive of connection to any circuitry of the plurality of stacks of semiconductor devices.

8. The semiconductor device assembly of claim 1, further comprising a plurality of silicon slugs including a continuous body of silicon extending from the device connection layer to the RDL, each of the silicon slugs including a TSV comprising a continuously tapering body of conductive metal that electrically couples the multi-reticle semiconductor device to an external package contact of the plurality of external package contacts.

9. The semiconductor device assembly of claim 1, wherein a region of the gap fill material extending between the device connection layer and the RDL is seamless.

10. A semiconductor device assembly, comprising:
a redistribution layer (RDL) including:
an external surface including a plurality of external contacts,
an internal surface including a plurality of internal contacts, and
a plurality of conductors operably coupling individual ones of the plurality of internal contacts to individual ones of the plurality of external contacts;
a device connection layer including:
a first surface having a first plurality of contact pads,
a second surface opposite the first surface and having a second plurality of contact pads,
a first plurality of conductive structures electrically coupling each of the first plurality of contact pads to a corresponding contact pad of the second plurality of contact pads, and
a second plurality of conductive structures electrically coupling each of a first subset of the second plurality of contact pads to a corresponding contact pad of a second subset of the second plurality of contact pads; and
a plurality of stacks of semiconductor devices disposed between the RDL and the device connection layer, horizontally spaced apart by a gap fill material, and electrically coupling individual ones of the plurality of internal contacts to individual ones of the first plurality of contact pads through TSVs disposed in the plurality of stacks.

11. The semiconductor device assembly of claim 10, wherein a region of the gap fill material extending between the device connection layer and the RDL is seamless.

12. The semiconductor device assembly of claim 10, wherein the gap fill material comprises silicon oxide, silicon nitride, a mold material, or a combination thereof.

13. The semiconductor device assembly of claim 10, further comprising a plurality of through gap fill vias extending from the RDL to the device connection layer, each of the through-gap fill vias comprising a continuously tapering body of conductive metal.

14. The semiconductor device assembly of claim 10, further comprising a plurality of silicon slugs including a continuous body of silicon extending from the device connection layer to the RDL, each of the silicon slugs including a TSV comprising a continuously tapering body of conductive metal that electrically couples the multi-reticle semiconductor device to an external package contact of the plurality of external package contacts.

15. A method of making a semiconductor device assembly, comprising:
providing a semiconductor device sub-assembly, the semiconductor device sub-assembly including:
a redistribution layer (RDL) including an external surface including a plurality of external contacts, an internal surface including a plurality of internal contacts, and a plurality of conductors operably coupling individual ones of the plurality of internal contacts to individual ones of the plurality of external contacts;
a device connection layer including a first surface having a first plurality of contact pads, a second surface opposite the first surface and having a second plurality of contact pads, a first plurality of conductive structures electrically coupling each of the first plurality of contact pads to a corresponding contact pad of the second plurality of contact pads, and a second plurality of conductive structures electrically coupling each of a first subset of the second plurality of contact pads to a corresponding contact pad of a second subset of the second plurality of contact pads; and
a plurality of stacks of semiconductor devices disposed between the RDL and the device connection layer, horizontally spaced apart by a gap fill material, and electrically coupling individual ones of the plurality of internal contacts to individual ones of the first plurality of contact pads through TSVs disposed in the plurality of stacks; and
bonding a second semiconductor device to the second surface of the device connection layer of the semiconductor device sub-assembly, wherein the second semiconductor device includes first and second circuit regions separated from one another by a reticle-edge region absent any electrical conductors, such that bonding the second semiconductor device to the semiconductor device sub-assembly electrically couples the first and second circuit regions to each other through the second plurality of conductive structures.

16. The method of claim 15, wherein bonding the second semiconductor device to the second surface of the device connection layer comprises forming a hybrid bond including dielectric-dielectric bonds and metal-metal bonds.

17. The method of claim 15, wherein the hybrid bond is exclusive of any solder material.

18. The method of claim 15, wherein bonding the second semiconductor device to the semiconductor device sub-assembly comprises a wafer-level bonding operation.

19. The method of claim 15, further comprising forming, in the semiconductor device sub-assembly, through-gap fill vias extending from the RDL to the device connection layer, each of the through-gap fill vias comprising a continuously tapering body of conductive metal.

20. The method of claim 15, further comprising forming, in the semiconductor device sub-assembly, a plurality of silicon slugs including a continuous body of silicon extending from the device connection layer to the RDL, each of the silicon slugs including a TSV comprising a continuously tapering body of conductive metal that electrically couples the multi-reticle semiconductor device to an external package contact of the plurality of external package contacts.
